(19) United States
(12) Patent Application Publication
(10) Pub. No.: US 2007/0178620 A1
(43) Pub. Date: Aug. 2, 2007

(54) Method of Forming Copper Indium Gallium Containing Precursors And Semiconductor Compound Layers

(76) Inventor: BULENT M. BASOL, Manhattan Beach, CA (US)

Correspondence Address: PILLSBURY WINTHROP SHAW PITTMAN LLP, P.O. BOX 10500, MCLEAN, VA, 22102, US

(21) Appl. No.: 11/670,884

(22) Filed: Feb. 2, 2007

Related U.S. Application Data
(60) Provisional application No. 60/764,820, filed on Feb. 2, 2006.
(60) Provisional application No. 60/744,654, filed on Apr. 11, 2006.

(51) Int. Cl. H01L 21/00

(52) U.S. Cl. 438/94; 438/95; 257/E21.117

(57) ABSTRACT

The present invention relates to methods of preparing polycrystalline thin films of semiconductors for radiation detectors and solar cells and the films resulting therefrom. In one aspect, the present invention provides a first type of particles and a second type of particles, wherein the first type of particles have a Cu/(In+Ga) molar ratio of at least 1.38. In another aspect the present invention provides a first type of particles containing a Cu-Group IIIA alloy wherein a molar ratio of Cu to Group IIIA material within each of the particles is at least 1.38.

### CLAIM OF PRIORITY

The present application claims priority to, and expressly incorporates by reference, U.S. Provisional Appln. Ser. No. 60/764,820 filed Feb. 2, 2006, entitled “Method of Forming Copper Indium Gallium Containing Compound Layers” and to U.S. Provisional Appln. Ser. No. 60/744,654 filed Apr. 11, 2006 entitled “Method of Forming Copper Indium Gallium Containing Precursors and Semiconductor Compound Layers”.

### FIELD OF THE INVENTION

The present invention relates to methods of preparing polycrystalline thin films of semiconductors for radiation detectors and solar cells and the films resulting therefrom.

### BACKGROUND

Solar cells convert sunlight directly into electricity. These electronic devices are commonly fabricated on silicon wafers. However, the cost of electricity generated using silicon-based solar cells is rather high. To make solar cells more economically viable, low-cost, thin-film growth techniques that can deposit high-quality light-absorbing semiconductor materials need to be developed.

Cu(In,Ga)(S,Se)₂ compounds are Group IB-IIIA-VIA materials with Group IB=Cu, Group IIIA=In and/or Ga, and Group VIA=Se and/or S. These semiconductor compounds are excellent absorber materials for thin-film solar cell structures provided that their structural and electronic properties are good. An important compositional parameter of Cu(In,Ga)(S,Se)₂ thin films is the molar ratio of Cu/(In+Ga). The typically acceptable range of this molar ratio for high-efficiency solar cell absorbers is about 0.70-1.0, although in some cases when the compound is doped with a dopant such as sodium (Na), potassium (K) or lithium (Li), this ratio can go even lower. If the Cu/(In+Ga) molar ratio exceeds 1.0, however, a low-resistivity copper selenide or sulfide phase precipitates and deteriorates the performance of the device due to electrical shorting paths through the absorber. Therefore, control of the Cu/(In+Ga) ratio is important for any technique that is used for the preparation of Cu(In,Ga)(S,Se)₂ films for radiation detector or solar cell applications. The Ga/(In+Ga) ratio is also important to control since this ratio determines the bandgap of the absorber. Laboratory experience to date has shown that best device efficiencies are obtained for Ga/(In+Ga) ratios in the range of 0.1-0.3, more preferably in the range of 0.2-0.3.

One approach that yielded high-quality Cu(In,Ga)Se₂ films for solar cell applications is co-evaporation of Cu, In, Ga and Se onto heated substrates in a vacuum chamber. This technique so far yielded devices with over 19% conversion efficiency. However, it is not easily adaptable to low-cost production of large-area films, mainly because control of Cu/(In+Ga) and Ga/(In+Ga) ratios by evaporation over large-area substrates is difficult, materials utilization is low and the cost of vacuum equipment is high.

Since compositional control, especially the control of the Cu/(In+Ga) ratio is important for Cu(In,Ga)(S,Se)₂ compounds, attempts have been made to fix this ratio in an initial material, before the deposition process, and then transfer this fixed composition into a thin film formed using this initial material. T. Arita et al. in their 1988 publication [20th IEEE PV Specialists Conference, 1988, page 1650] described a screen printing technique that involved mixing and milling pure Cu, In and Se powders in the compositional ratio of 1:1:2 and forming a screen printable paste, screen printing the paste on a substrate, and sintering this film to form the compound layer. They reported that although they had started with elemental Cu, In and Se powders, after the milling step the paste contained the CuInSe₂ phase. Solar cells fabricated on the sintered layers had very low efficiencies.

The technique of; i) mixing elemental particles (such as Cu particles and In particles) to form a paste or an ink, ii) depositing the paste on a substrate to form a precursor layer, and, iii) exposing the precursor layer to a Group VIA material such as Se to form the compound, was first disclosed by A. Vervaet et al. [Proceedings of 10^{th} European Photovoltaic Solar Energy Conference, 1991, p. 900]. The properties of such precursor layers were reported to be poor because of the large size of the In particles, suggesting that use of much smaller Cu, and elemental Group IIIA particles in a paste or ink would yield promising results since the formation temperature of the compound would be reduced considerably compared to precursor layers already containing the compound phase as in the Arita reference.

U.S. Pat. No. 5,985,691 issued to B. M. Basol et al describes another particle-based method to form a Group IB-IIIA-VIA compound film, where IB=Cu, Ag, Au, IIIA=In, Ga, Al, Tl, and VIA=S, Se, Te. The described method includes the steps of preparing a source material, depositing the source material on a base to form a precursor, and heating the precursor to form a film. In that invention the source material, instead of containing only elemental Cu, In and Ga particles as in the Vervaet reference above, includes Group IB-IIIA alloy-containing particles having at least one Group IB-IIIA alloy phase, with Group IB-IIIA alloys constituting greater than 50 molar percent of the Group IB elements and greater than 50 molar percent of the Group IIIA elements in the source material. The powder is milled to reduce its particle size and then used in the preparation of an ink which is deposited on the substrate in the form of a precursor layer. The precursor layer is then exposed to an atmosphere containing Group VIA vapors at elevated temperatures to convert the film into the compound. The precursor films, deposited using this technique, were porous and they yielded porous CuInSe₂ layers with small-grain regions as reported by G. Norsworthy et al. [Solar Energy Materials and Solar Cells, 2000, vol. 60, page 127]. Porous solar cell absorbers yield unstable devices because of the large internal surface area within the device. Also small grains limit the conversion efficiency of solar cells.

PCT application No. WO 99/17889 (Apr. 15, 1999) by C. Eberspacher et al. describes methods for forming solar cell materials from particulates where various approaches of making the particulates of various chemical compositions and depositing them on substrates are discussed.

As the above brief review of prior art demonstrates, there have been attempts to use i) Cu(In,Ga)Se₂ compound powders, ii) oxide containing particles, iii) mixture of elemental Cu and Group IIIA particles, and, iv) Cu-(In,Ga) alloy powders with (In,Ga)-rich compositions, to form precursor layers which were then treated at high temperatures to form Cu(In,Ga)Se₂ compound films. In the approach utilizing metallic powders comprising Cu-(In,Ga) alloy particles and other particles [see U.S. Pat. No. 5,985,691], the (In+Ga) molar content within the alloy particles was more than 50% of the total (In+Ga) molar content of the powder. These techniques were successful in demonstrating compositional control. However, repeatability and the overall yield of the process need high quality powder material with repeatable composition and phase content.

### SUMMARY OF THE INVENTION

The present invention relates to methods of preparing polycrystalline thin films of semiconductors for radiation detectors and solar cells and the films resulting therefrom.

In one aspect the present invention includes a method of forming a Cu(In,Ga)(Se,S)₂ compound layer on a substrate, in which the method includes preparing a powder, and depositing the powder onto the substrate in the form of a precursor film, wherein the powder comprises a first type of particles and a second type of particles, and wherein the first type of particles have a Cu/(In+Ga) molar ratio of at least 1.38.

In another aspect the present invention provides a precursor film deposited on a base comprising a first type of particles containing a Cu-Group IIIA alloy wherein a molar ratio of Cu to Group IIIA material within each of the particles is at least 1.38.

In yet another aspect, there is provided a Cu(In,Ga)(S,Se)₂ layer on the base formed by reacting a precursor film with at least one of S and Se, and wherein the precursor film is deposited on a base and comprises a first type of particles containing a Cu-Group IIIA alloy wherein a molar ratio of Cu to Group IIIA material within each of the particles is at least 1.38.

### BRIEF DESCRIPTION OF THE DRAWINGS

These and other aspects and features of the present invention will become apparent to those of ordinary skill in the art upon review of the following description of specific embodiments of the invention in conjunction with the accompanying figures, wherein:

FIG. 1 is a chart showing the steps of a method used to grow Cu(In,Ga)(S,Se)₂ compound layer.

FIG. 2 is a drawing of the copper-gallium phase diagram (not all details shown, only the relevant parts drawn).

FIG. 3 is a drawing of the gallium-indium phase diagram (not all details shown, only the relevant parts drawn).

FIG. 4 is a drawing of the copper-indium phase diagram (not all details shown, only the relevant parts drawn).

### DETAILED DESCRIPTION

Although the present invention is described for the growth of Cu(In,Ga)(S,Se)₂ layers tellurium may also be included into the composition to grow Cu(In,Ga)(S, Se, Te)₂ films. The compound layer may additionally contain dopants such as potassium (K), sodium (Na), lithium (Li), phosphorous (P), arsenic (As), antimony (Sb) and bismuth (Bi) to enhance its p-typeness and its electrical and optical properties.

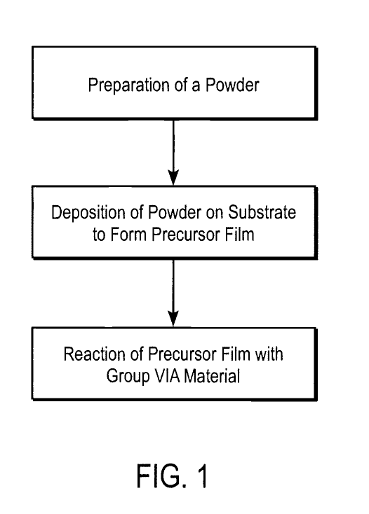

FIG. 1 shows the steps of a compound film growth process of the present invention. The first step of the process involves preparation of a powder wherein the powder comprises at least two types of particles. The first type of particles each has a composition of Cu—Ga where the Ga molar content is less than or equal to about 42%, preferred range being 20-42%, to form compound layers with high Ga content. In other words the Cu/Ga molar ratio is more than or equal to 1.38 within the particles of Cu—Ga. The second type of particles constituting the powder each has a composition that is more than 82% In. Preferably the second type of particles each has a composition of pure In. Referring back to FIG. 1, after the preparation of the powder, the powder is deposited onto a substrate in the form of a precursor film. The preferred method of deposition involve formation of a dispersion or ink comprising the powder and deposition of the dispersion onto the substrate in the form of a thin layer using common techniques such as doctor-blading, spraying, ink jet printing, roll coating etc. The dispersion may be prepared by well known techniques such as sonication of the mixture of the powder, a solvent (such as water) and various dispersing agents and/or surfactants available from companies such as Rohm and Haas. Alternately, dry powder deposition techniques such as spraying etc. may also be utilized. After the precursor film comprising the powder is formed on the substrate, it is reacted with at least one Group VIA material (Se, S, Te) to form the Cu(In,Ga)(Se,S,Te)₂ compound on the substrate. There may be additional optional steps of drying and/or heat treatment between the steps of precursor film deposition and reaction with Group VIA material.

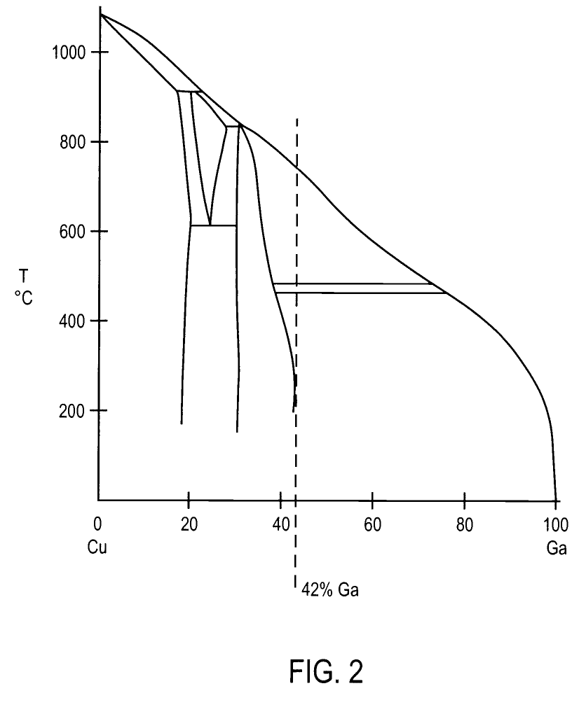

FIG. 2 shows the binary phase diagram of the Cu—Ga material system (reference: M. Hansen, “Constitution of binary alloys”, Mc Graw Hill, 1958, page: 583). As can be seen from this figure, for temperatures of 200-400 C, a Cu—Ga material containing more than about 42% Ga, would contain a Ga rich phase containing at least 90% Ga. This Ga-rich phase would be in the form of a liquid at the temperature range above Ga melting point, and even at lower temperatures. It should be noted that in techniques used to form the first type of particles, such as melt spraying or sputtering from a Cu—Ga target into an inert gas and arc methods that form nano-droplets from Cu—Ga targets or wires etc., the Cu—Ga target, wire or source material gets heated to at least the temperature range of 200-400 C and then particles formed from it gets quenched to room temperature. If the composition of the target, wire or source material has Ga content of more than 42%, the particles formed from it would contain the low melting Ga phase causing particles to stick to each other and cause morphological and compositional non-uniformities in the precursor films. Therefore, it is important to have the target, wire or source composition to have less than or equal to 42% Ga and more than or equal to 58% Cu, and to form first type of particles with the same composition. As mentioned before, if a high Ga content (such as Ga/(Ga+In) ratio of more than 0.2) is needed in the final compound layer, the source composition is preferably in the range of (20% Ga+80% Cu) and (42% Ga+58% Cu), i.e. Cu_{0.8}Ga_{0.2} and Cu_{0.58}Ga_{0.42}. This composition is directly carried over to the first type of particles obtained using the source material.

It is possible to add also In to the composition of the first type of particles. However, in any case, molar percentage of (In+Ga) in the alloy particles should be less than or equal to 42%. For example, the composition of the first type of particles may be (42% Ga and 58% Cu), or (38% Ga, 4% In and 58% Cu), in other words Cu_{0.58}Ga_{0.42} or Cu_{0.58}In_{0.04}Ga_{0.38}.

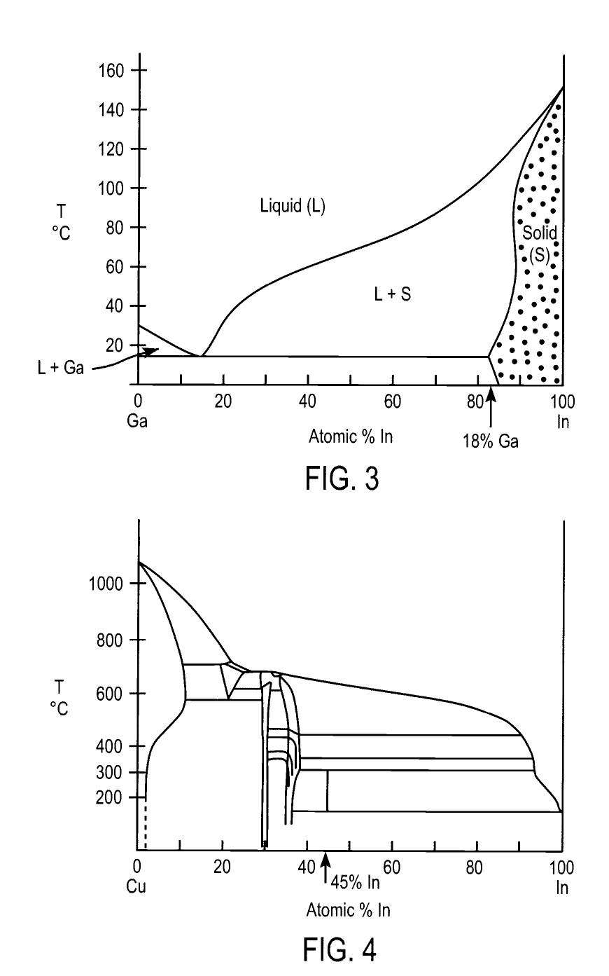

The second type of particles is, preferably, In particles. However, up to about 18% of Ga may also be included in the composition of the second type of particles because there is a solid solution of In in Ga up to about this composition as can be seen from FIG. 3. This solid-solution region is labeled Solid (S) in FIG. 3 (reference: M. Hansen, “Constitution of binary alloys”, Mc Graw Hill, 1958, page: 745). It should be noted that outside this region, particles of In—Ga would always contain a liquid at temperatures above about 16 C and, as explained before, this should be avoided since liquid phase within the particles causes particles to stick together in the powder or ink formulation and cause non-uniformities in the precursor layer and then in the compound film formed after reacting the precursor layer with at least one Group VIA material.

The powder may comprise third type of particles with a composition of Cu—In wherein the In molar content may change between 0% and 45%. FIG. 4 is a binary phase diagram for Cu—In (reference: M. Hansen, “Constitution of binary alloys”, Mc Graw Hill, 1958, page: 591). As can be seen from this diagram, for Cu—In compositions containing more than 45% In, an In-rich liquid phase would form at temperatures higher than the melting temperature of In, which is about 156 C. To avoid the formation of this liquid phase within the particles, In content in the Cu—In particles needs to be less than or equal to 45%, preferably less than 40%. It should be noted that for Cu—In compositions in the range of (40% In+60% Cu) and (45% In+55% Cu) an In-rich liquid phase may form at temperatures above about 300 C. However, for compositions with In content less than 40%, liquid phase formation temperature is above 400 C, and therefore these compositions are more preferable.

As described above, the present invention utilizes a powder wherein the low melting phases within the metallic particles making up the powder are eliminated or minimized. Specifically, no phase is allowed within the particles with melting point of less than about 156 C, which is the melting point of In. The operational region of the present invention may be formulated as follows.

The powder of the present invention comprises Cu₍₁₋ₓ₎Gaₓ particles, and at least one of Cu_{(1-y)}In_{y} particles and In₍₁₋ₖ₎Gaₖ particles, where 0.2≦x≦0.42, 0≦y≦0.45, 0≦k≦0.18, and where the total (Ga+In) molar content of the Cu—Ga and Cu—In alloy particles in the powder is less than 50% of the total (Ga+In) molar content of the powder. Preferably, the ranges of x, y and z are; 0.2≦x≦0.42, 0≦y≦0.4, 0≦k≦0.18, and the total (Ga+In) molar content of the Cu—Ga and Cu—In alloy particles in the powder is less than 50% of the total (Ga+In) molar content of the powder. More preferably, the ranges of x, y and z are 0.2≦x≦0.42, 0≦y≦0.35, 0≦k≦0.18, and the total (Ga+In) molar content of the Cu—Ga and Cu—In alloy particles in the powder is less than 50% of the total (Ga+In) molar content of the powder. Now, some examples will be given to further explain the compositions of various powder materials that maybe used to practice the present invention.

### EXAMPLE 1

A powder may comprise Cu—Ga particles, Cu particles and In particles. Cu—Ga particles may have a composition where Cu/Ga ratio is more than or equal to 1.38. If Cu—Ga particles are Cu_{0.6}Ga_{0.4} particles, 0.75 moles of these particles may be mixed with 0.7 moles of In particles and 0.55 moles of Cu particles to obtain a powder with Cu/(Ga+In) ratio of 1 and Ga/(Ga+In) ratio of 0.3. This can be seen from the equation:
0.75 Cu_{0.6}Ga_{0.4}+0.7 In+0.55 Cu=CuIn_{0.7}Ga_{0.3}

It should be noted that, in this case, the molar Ga content of the Cu—Ga alloy particles in the powder is (0.75×0.4=0.3) and the molar (Ga+In) content of the powder is (0.3+0.7=1.0). Therefore, the total (Ga+In) molar content of the alloy particles is 30% of the total (Ga+In) molar content of the powder.

Those skilled in the art would recognize that by changing the relative amounts of the three types of particles above, one can get various Cu/(Ga+In) and Ga/(Ga+In) ratios that are good for solar cell fabrication.

### EXAMPLE 2

A powder may comprise Cu—Ga particles, Cu—In particles and In particles. Cu—Ga particles may have a composition where Cu/Ga ratio is more than or equal to 1.38. If Cu—Ga particles are Cu_{0.6}Ga_{0.4} particles, and Cu—In particles are Cu_{0.8}In_{0.2} particles, then 0.71 moles of the Cu_{0.6}Ga_{0.4} particles and 0.71 moles of Cu_{0.8}In_{0.2} particles maybe mixed with 0.58 moles of In particles to obtain a powder with Cu/(Ga+In) ratio of about 1 and Ga/(Ga+In) ratio of about 0.28. This can be seen from the equation:
0.71 Cu_{0.6}Ga_{0.4}+0.71 Cu_{0.8}In_{0.2}+0.58 In≈CuIn_{0.72}Ga_{0.28}

It should be noted that, in this case, the molar (Ga+In) content of the Cu—Ga alloy particles and the Cu—In alloy particles in the powder is about (0.28+0.14=0.42) and the molar (Ga+In) content of the powder is about 1.0. Therefore, the total (Ga+In) molar content of the alloy particles is 42% of the total (Ga+In) molar content of the powder.

Those skilled in the art would recognize that by changing the relative amounts of the three types of particles above one can get various Cu/(Ga+In) and Ga/(Ga+In) ratios that are good for solar cell fabrication. Also, additional Cu and/or In particles may be added to the powder within the limits of this invention. However, in this case the relative Ga content would get lower in the powder.

### EXAMPLE 3

A powder may comprise Cu—Ga particles, Cu—In particles and In particles. Cu—Ga particles may have a composition where Cu/Ga ratio is more than or equal to 1.38. If Cu—Ga particles are Cu_{0.7}Ga_{0.3} particles, and Cu—In particles are Cu_{0.7}In_{0.3} particles, then 0.71 moles of the Cu_{0.7}Ga_{0.3} particles and 0.71 moles of Cu_{0.7}In_{0.3} particles may be mixed with 0.58 moles of In particles to obtain a powder with Cu/(Ga+In) ratio of about 1 and Ga/(Ga+In) ratio of about 0.21. This can be seen from the equation:
0.71 Cu_{0.7}Ga_{0.3}+0.71 Cu_{0.7}In_{0.3}+0.58 In≈CuIn_{0.79}Ga_{0.21}

It should be noted that, in this case, the molar (Ga+In) content of the Cu—Ga alloy particles and the Cu—In alloy particles in the powder is about (0.21+0.21=0.42) and the molar (Ga+In) content of the powder is about 1.0. Therefore, the total (Ga+In) molar content of the alloy particles is 42% of the total (Ga+ln) molar content of the powder.

Those skilled in the art would recognize that by changing the relative amounts of the three types of particles above one can get various Cu/(Ga+In) and Ga/(Ga+In) ratios that are good for solar cell fabrication. Also, additional Cu and/or In particles may be added to the powder within the limits of this invention. However, in this case the relative Ga content would get lower in the powder.

### EXAMPLE 4

A powder may comprise Cu—Ga particles and In—Ga particles. Cu—Ga particles may have a composition where Cu/Ga ratio is more than or equal to 1.38. If Cu—Ga particles are Cu_{0.8}Ga_{0.2} particles, and In—Ga particles are In_{0.9}Ga_{0.1} particles, then 125 moles of the Cu_{0.8}Ga_{0.2} particles and 0.75 moles of In_{0.9}Ga_{0.1} particles may be mixed to obtain a powder with Cu/(Ga+In) ratio of about 1 and Ga/(Ga+In) ratio of about 0.325. This can be seen from the equation:
1.25 Cu_{0.8}Ga_{0.2}+0.75 In_{0.9}Ga_{0.1}≈CuIn_{0.675}Ga_{0.325}

It should be noted that, in this case, the molar Ga content of the Cu—Ga alloy particles in the powder is about (0.2×1.25=0.25) and the molar (Ga+In) content of the powder is about 1.0. Therefore, the total (Ga+In) molar content of the Cu—Ga alloy particles is 25% of the total (Ga+In) molar content of the powder.

Those skilled in the art would recognize that by changing the relative amounts of the two types of particles above one can get various Cu/(Ga+In) and Ga/(Ga+In) ratios that are good for solar cell fabrication. Also, additional Cu and/or In particles may be added to the powder within the limits of this invention. However, in this case the relative Ga content would get lower in the powder.

In all the examples above additional metallic alloy particles with a ternary composition of Cu—In—Ga may be added to the powder formulation. However, in all cases, the total (Ga+In) molar content of the Cu—Ga and/or Cu/In and/or Cu—In—Ga alloy particles should be less than 50% of the total (Ga+In) molar content of the powder. More preferably, the total (Ga+In) molar content of the Cu—Ga and/or Cu/In and/or Cu—In—Ga alloy particles should be less than 42% of the total (Ga+In) molar content of the powder.

The first type of particles (Cu—Ga and/or Cu—In—Ga particles), the second type of particles (In—Ga particles) and third type of particles (Cu—In particles), when mixed with each other in various ways as explained above collectively constitute a metallic component of the powder of this invention. The Cu/(In+Ga) molar ratio in the metallic component of the powder is in the range of 0.7-1, and the Ga/(Ga+In) molar ratio in the metallic component of the powder is in the range of 0.05-0.40, preferably in the range of 0.2-0.3.

The powder of this invention may include particles of at least one Group VIA material. They are preferably Se particles although they may also contain S and/or Te. It should be noted that all percentages cited in this application and atomic percentages and the size of the particles are preferably less than or equal to 200 nm. Particles are preferably spherical in shape or flat in the form of nano plates so that when they are deposited in the form of a precursor film they form a dense structure.

During the reaction step of FIG. 1, Cu, Ga and In in the precursor film are reacted with at least one Group VIA material to form the compound. The Group VIA material may be provided by a vapor (such as hydrogen selenide, hydrogen sulfide, Se vapor, S vapor etc.) or it may already be within the precursor film in the form of third type of particles described above. Alternately, a thin layer of a Group VIA material may be deposited on the precursor film and then reacted with the precursor film. The reaction temperature may be in the 250-600 C range, preferably between 400-550 C. Reaction times may vary from a few seconds (in the case of rapid thermal processing or laser treatment) to over 30 minutes (in the case of furnace annealing).

After the formation of the Cu(In,Ga)(Se,S)₂ compound layer, solar cells may be fabricated on this layer using commonly known techniques. One method involves deposition of a thin CdS layer and a transparent conductive oxide (such as ZnO and/or indium tin oxide) layer on the compound layer. The substrate on which the compound layer is formed may be a foil or glass sheet coated with an ohmic contact material such as Mo.

Although the present invention is described with respect to certain preferred embodiments, modifications thereto will be apparent to those skilled in the art.

1. A method of forming a Cu(In,Ga)(Se,S)₂ compound layer on a substrate comprising,
preparing a powder, and
depositing the powder onto the substrate in the form of a precursor film
wherein the powder comprises a first type of particles and a second type of particles, and
wherein the first type of particles each comprises only Cu and at least one of In and Ga, and each particle has a Cu/(In+Ga) molar ratio of at least 1.38.

2. The method according to claim 1 wherein the second type of particles are made of Group IIIA materials.

3. The method according to claim 2 wherein the second type of particles are indium particles.

4. The method according to claim 3 wherein the Cu/Ga ratio is smaller than 4.

5. The method according to claim 3 wherein the first type of particles are Cu—Ga particles with Cu/Ga molar ratio of at least 1.38.

6. The method according to claim 5 wherein the Cu/Ga ratio is smaller than 4.

7. The method according to claim 5 further including a step of reacting the precursor film with at least one of Se and S.

8. The method according to claim 7 wherein the step of reacting is carried out at a temperature range of 250-600 C.

9. The method according to claim 3 further including a step of reacting the precursor film with at least one of Se and S.

10. The method according to claim 9 wherein the step of reacting is carried out at a temperature range of 250-600 C.

11. The method according to claim 2 further including a step of reacting the precursor film with at least one of Se and S.

12. The method according to claim 11 wherein the step of reacting is carried out at a temperature range of 250-600 C.

13. The method according to claim 2 wherein the Cu/(In+Ga) ratio is smaller than 4.

14. The method according to claim 13 wherein the powder further comprises a third type of particles comprising a Group VIA material.

15. The method according to claim 14 wherein the third type of particles are Se particles.

16. The method according to claim 15 further comprising the step of heating to form the Cu(In,Ga)(S,Se)₂ compound layer.

17. The method according to claim 16 wherein the heating is carried out at a temperature range of 250-600 C.

18. The method according to claim 11 further comprising the step of depositing a layer of a Group VIA material on the precursor film to form a stack.

19. The method according to claim 18 further comprising the step of heating the stack to a temperature of 400-600 C. to react the precursor film with the Group VIA material.

20. The method according to claim 1 wherein the first type of particles are Cu—Ga particles with Cu/Ga molar ratio of at least 1.38.

21. The method according to claim 20 wherein the Cu/Ga ratio is smaller than 4.

22. The method according to claim 20 further including a step of reacting the precursor film with at least one of Se and S.

23. The method according to claim 22 wherein the step of reacting is carried out at a temperature range of 250-600 C.

24. The method according to claim 1 further including a step of reacting the precursor film with at least one of Se and S.

25. The method according to claim 24 wherein the step of reacting is carried out at a temperature range of 250-600 C.

26. The method according to claim 1 wherein the Cu/(In+Ga) ratio is smaller than 4.

27. A precursor film deposited on a base comprising a first type of particles containing a Cu-Group IIIA alloy wherein a molar ratio of Cu to Group IIIA material within each of the particles is at least 1.38.

28. The precursor film of claim 27 wherein the Group IIIA material comprises Ga.

29. The precursor film of claim 28 wherein the Group IIIA material comprises In.

30. The precursor film of claim 27 further comprising at least one of Cu particles, In particles, Cu—In particles and In—Ga particles.

31. The precursor film of claim 30 wherein the In—Ga particles each comprises less than or equal to 18 atomic percent Ga.

32. The precursor film of claim 30 wherein the Cu—In particles each comprises less than or equal to 45 atomic percent In.

33. A Cu(In,Ga)(S,Se)₂ layer on the base formed by reacting the precursor film of claim 30 with at least one of S and Se.

34. The precursor film of claim 27 further comprising particles of a Group VIA material.

35. The precursor film of claim 34 wherein the Group VIA material is Se.

36. A Cu(In,Ga)(S,Se)₂ layer on the base formed by reacting the precursor film of claim 35 with at least one of S and Se.

37. A Cu(In,Ga)(S,Se)₂ layer on the base formed by reacting the precursor film of claim 27 with at least one of S and Se.
